(19) United States
(12) Patent Application Publication
(10) Pub. No.: US 2026/0354114 A1
(43) Pub. Date: Nov. 5, 2026

(54) SEMICONDUCTOR DEVICE MANUFACTURING APPARATUS AND METHOD FOR SUCTIONING MEMBER

(71) Applicant: SHINKAWA LTD., Tokyo (JP)

(72) Inventor: Kohei Seyama, Tokyo (JP)

(73) Assignee: SHINKAWA LTD., Tokyo (JP)

(21) Appl. No.: 19/120,214

(22) PCT Filed: Aug. 10, 2023
(86) PCT No.: PCT/JP2023/029287

§ 371 Date: Apr. 10, 2025

(30) Foreign Application Priority Data
Oct. 14, 2022 (JP) 2022-165323

(51) Int. Cl. H10P 72/78; H10P 72/00

(52) U.S. Cl. CPC H10P 72/78; H10P 72/0446

(57) ABSTRACT

This semiconductor device manufacturing apparatus includes a reference jig larger than the semiconductor chip; and a mounting tool that individually suctions and transfers the semiconductor chip and the reference jig. The mounting tool has: a base surface that contacts an upper surface of the reference jig when the reference jig is suction held; and a second block that protrudes from the base surface and has a suction hole formed therein, the second block contacting an upper surface of the semiconductor chip when the semiconductor chip is suction held. The reference jig has a receiving recess that receives the second block and forms a closed space between itself and the mounting tool when suction held by the mounting tool.

### TECHNICAL FIELD

This specification discloses a semiconductor device manufacturing apparatus including a mounting tool that individually suctions and transfers a semiconductor chip and a reference jig larger in size than the semiconductor chip, and a method for transferring members.

### RELATED ART

In a semiconductor device manufacturing apparatus, the mounting tool suction holds the semiconductor chip. Then, while suctioning the semiconductor chip, the mounting tool moves and bonds the semiconductor chip to a substrate or the like.

Such mounting tools may suction hold not only the semiconductor chip but also the reference jig larger in size than the semiconductor chip. For example, for position calibration of the mounting tool, a transparent plate-like calibration jig may be suction held by the mounting tool and transferred to a predetermined position. Moreover, to measure the flatness of a substrate, a measurement jig larger in size than the semiconductor chip may be suction held by the mounting tool. Hereinafter, jigs that are larger in size than semiconductor chips and are suction held by the mounting tool, such as calibration jigs and measurement jigs, are called “reference jigs”.

### CITATION LIST

### Patent Literature

Patent Document 1: Japanese Patent Application Laid-Open Publication No. 2007-165594

### SUMMARY OF INVENTION

### Technical Problem

Here, the reference jig is significantly larger than the semiconductor chip. When attempting to suction hold components with such significantly different sizes using a single mounting tool, various problems were likely to occur.

For example, if the suction surface of the mounting tool is made small to match the size of the semiconductor chip, it cannot properly suction the large reference jig. On the other hand, if the suction surface of the mounting tool is made large to match the size of the reference jig, when the semiconductor chip is suctioned, part of the suction surface may protrude from the semiconductor chip, risking interference with adjacent other semiconductor chips.

Moreover, Patent Document 1 discloses a technology where the bottom surface of a collet is formed in a hollow pyramidal shape. According to such a collet, multiple types of suction targets with different sizes may be suctioned. However, even with the collet of Patent Document 1, the problem of the part of the collet that protrudes from the suction object interfering with adjacent other members cannot be resolved.

Therefore, this specification discloses a semiconductor device manufacturing apparatus and a method for suctioning member that is capable of appropriately suction holding both semiconductor chips and reference jigs with a single mounting tool.

### Solution to Problem

A semiconductor device manufacturing apparatus disclosed in this specification includes: a reference jig larger in size than a semiconductor chip; and a mounting tool that individually suctions and transfers the semiconductor chip and the reference jig. The mounting tool includes: a base surface that contacts an upper surface of the reference jig when the reference jig is suction held; and a suction protrusion that protrudes from the base surface and has a suction hole formed therein, in which the suction protrusion contacts an upper surface of the semiconductor chip when the semiconductor chip is suction held. The reference jig has a receiving recess, in which the receiving recess receives the suction protrusion and forms a closed space between itself and the mounting tool when suction held by the mounting tool.

In this case, an external size of the suction protrusion may be smaller than an external size of the semiconductor chip.

Moreover, the receiving recess may have a shape without sharp corners.

Additionally, the reference jig may be a calibration jig or a measurement jig.

Furthermore, an external size of the receiving recess may be 50% or more of an external size of the reference jig.

A method for suctioning member disclosed in this specification is a suction method for individually suctioning a semiconductor chip and a reference jig larger in size than the semiconductor chip by a single mounting tool. The mounting tool includes: a base surface and a suction protrusion protruding from the base surface and having a suction hole formed therein. The reference jig has, on its upper surface, a receiving recess formed that completely accommodates the suction protrusion. The suction protrusion is brought into contact with the semiconductor chip when the semiconductor chip is suctioned by the mounting tool. The base surface is brought into contact with the upper surface of the reference jig in a state where the suction protrusion is accommodated in the receiving recess when the reference jig is suctioned by the mounting tool.

### Effects of Invention

According to the technology disclosed in this specification, both the semiconductor chip and the reference jig can be appropriately suction held by a single mounting tool.

### BRIEF DESCRIPTION OF DRAWINGS

FIG. 1 A schematic diagram showing the configuration of a semiconductor device manufacturing apparatus.

FIG. 2 A schematic diagram showing the configuration of a semiconductor device manufacturing apparatus.

FIG. 3 A plan view of a reference jig.

FIG. 4 A diagram showing the bonding of a semiconductor chip with the mounting tool.

FIG. 5 A diagram showing the transfer arrangement of the reference jig with the mounting tool.

FIG. 6A A diagram showing an example of another reference jig.

FIG. 6B A diagram showing another example of another reference jig.

FIG. 7 A diagram showing the bonding of a semiconductor chip with a tool of a comparative example.

FIG. 8 A diagram showing the transfer arrangement of a reference jig of a comparative example with the mounting tool.

### DESCRIPTION OF THE EMBODIMENTS

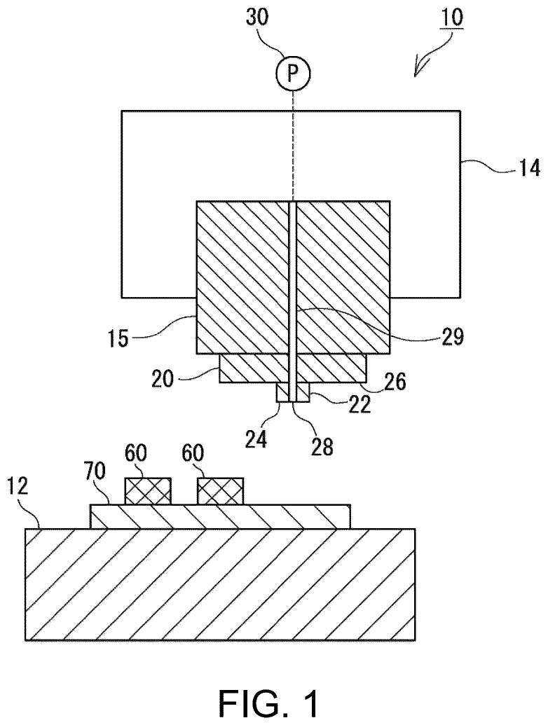

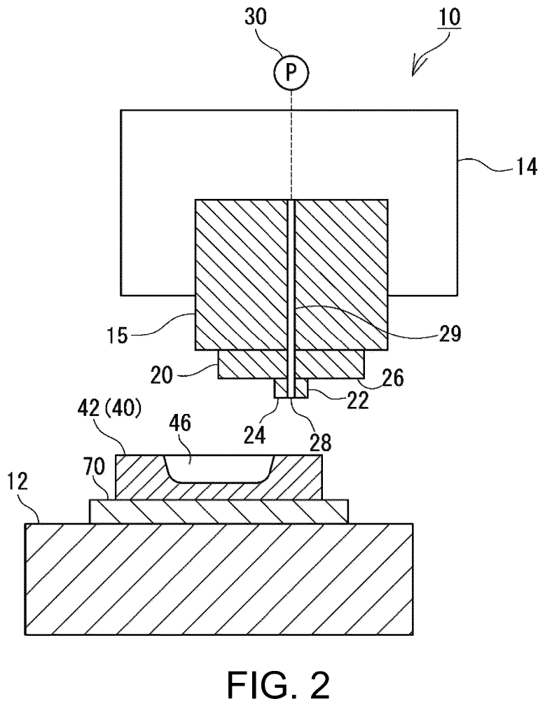

The configuration of a semiconductor device manufacturing apparatus 10 will be described below with reference to the drawings. FIG. 1 and FIG. 2 are schematic diagrams showing the configuration of the manufacturing apparatus 10. This manufacturing apparatus 10 manufactures a semiconductor device by bonding a semiconductor chip 60 on a bonding target. The bonding target is a substrate 70, or another semiconductor chip 60 bonded to the substrate 70.

The manufacturing apparatus 10 includes a stage 12, a mounting head 14, and a reference jig 40. The stage 12 is a platform on which the substrate 70 is placed. The stage 12 may have a heater (not shown) that heats the substrate 70.

The mounting head 14 is provided above an upper side of the stage 12. The mounting head 14 has a mounting tool 15 that is moveable in horizontal and vertical directions. The mounting tool 15 suction holds the semiconductor chip 60 on its bottom surface and transfers the semiconductor chip 60. The bottom part of the mounting tool 15 has a two-stage configuration in which a first block 20 and a second block 22 are stacked vertically. The external size of the first block 20 in the top view is sufficiently larger than the external size of the semiconductor chip 60. In addition, the bottom surface of the first block 20 functions as a base surface 26 that comes into contact with the upper surface of the reference jig 40 when the reference jig 40, which will be described later, is suction held.

The second block 22 protrudes downward from the bottom surface (i.e., the base surface 26) of the first block 20. This second block 22 functions as a suction protrusion for suction holding of the semiconductor chip 60. The external size of the second block 22 in the top view is smaller than the external size of the semiconductor chip 60. The bottom surface of this second block 22 functions as a suction surface 24 that comes into contact with the upper surface of the semiconductor chip 60 for suction holding of the semiconductor chip 60.

A suction hole 28 is formed on the suction surface 24. This suction hole 28 is fluidly connected to a suction pump 30 through a suction channel 29 formed inside the mounting tool 15. The suction pump 30 is provided outside the mounting tool 15 and applies negative pressure to the suction hole 28.

The reference jig 40 is a jig used to calibrate or measure various members related to the manufacturing apparatus 10. The reference jig 40 is, for example, a calibration jig 42 for calibrating the positioning function of the mounting tool 15. The calibration jig 42 is, for example, a plate-like member composed of transparent material such as glass. The calibration procedure using the calibration jig 42 is not particularly limited. For example, to calibrate the positioning function of the mounting tool 15, a jig-side marker (not shown) may be attached to the calibration jig 42 in advance. Then, in calibration, the calibration jig 42 is suction held and transferred by the mounting tool 15, and the calibration jig 42 is positioned and arranged with respect to a reference point of the substrate 70. Moreover, after positioning and arranging, the calibration amount of the positioning function of the mounting tool 15 may be identified based on the amount of position deviation between the reference point that may be observed through the transparent calibration jig 42 and the jig-side marker.

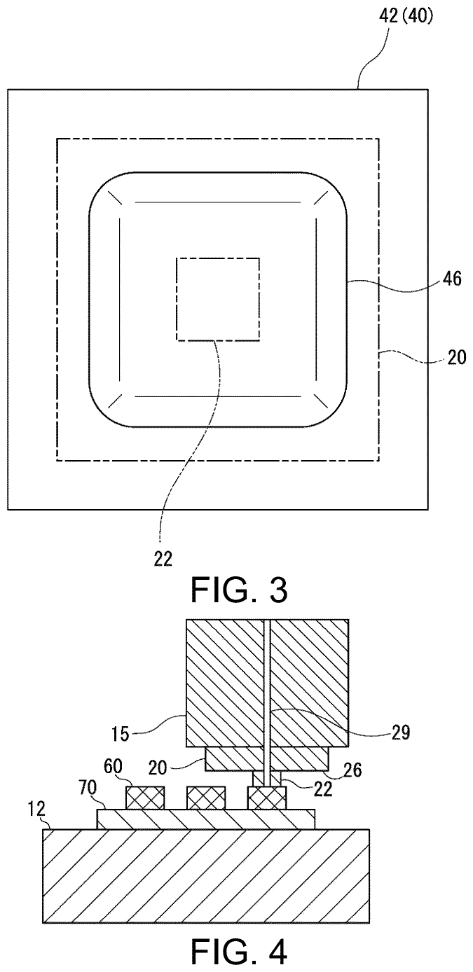

FIG. 3 is a plan view of the reference jig 40. Moreover, in FIG. 3, the two-dot chain line indicates the outline of the first block 20 and the second block 22 of the mounting tool 15. As evident from FIG. 2 and FIG. 3, the external size of the reference jig 40 is sufficiently larger than the external size of the semiconductor chip 60. Moreover, the external size of the reference jig 40 is larger than the external size of the first block 20 (and consequently, the external size of the base surface 26). Additionally, a receiving recess 46 for receiving the second block 22 is formed on the upper surface of the reference jig 40. Moreover, the external size of the receiving recess 46 is sufficiently larger than the external size of the second block 22. Furthermore, the depth of the receiving recess 46 is sufficiently greater than the height of the second block 22. Therefore, when the reference jig 40 is suction held by the mounting tool 15, the base surface 26 of the mounting tool 15 adheres to the upper surface of the reference jig 40, whereby the receiving recess 46 forms a closed space sealed by the mounting tool 15.

As evident from the description thus far, the mounting tool 15 in this example has a two-stage configuration at its bottom part, and the receiving recess 46 is formed on the upper surface of the reference jig 40. The reason for adopting this configuration is described in comparison with a comparative example.

FIG. 7 shows bonding of a semiconductor chip 60 using a mounting tool 15* as a comparative example. This mounting tool 15* does not have a second block 22 smaller than the semiconductor chip 60. Moreover, the bottom surface of the mounting tool 15*, that is, the bottom surface of the first block 20, is a flat surface without protrusions, and a suction hole 28 is formed on this bottom surface of the first block 20. When bonding the semiconductor chip 60 using such a mounting tool 15*, the upper surface of the semiconductor chip 60 is brought into contact with the bottom surface of the first block 20 and the semiconductor chip 60 is suction held. In this case, as evident from FIG. 7, a part of the bottom surface of the first block 20 protrudes outside the semiconductor chip 60. Consider the case of picking up the semiconductor chip 60 from a chip supply source (e.g., a diced wafer, etc.) in this state, or bonding the suction-held semiconductor chip 60 to a substrate 70. In this case, as shown in FIG. 7, the part of the first block 20 that protrudes outside the semiconductor chip 60 may interfere with adjacent other semiconductor chips 60, potentially causing damage to the other semiconductor chips 60.

Therefore, in this example, a second block 22 smaller than the external shape of the semiconductor chip 60 is provided on the bottom surface of the mounting tool 15. By adopting this configuration, as shown in FIG. 4, when bonding the semiconductor chip 60, interference between a part of the second block 22 and other semiconductor chips 60 can be effectively prevented.

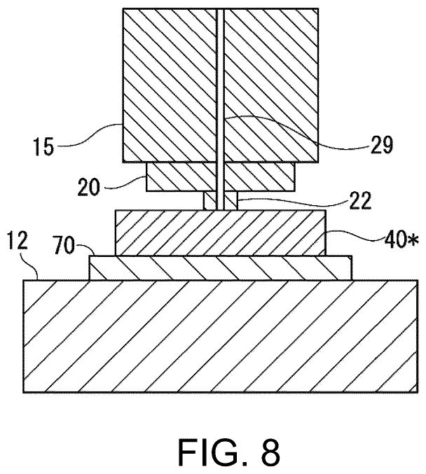

However, in the case of such a mounting tool 15, there was a problem that it was difficult to suction hold a reference jig 40* of a comparative example. FIG. 8 shows a state of suction holding the reference jig 40* of the comparative example using the mounting tool 15. The upper surface of the reference jig 40* of the comparative example is a flat surface, and the reference jig 40* does not have a receiving recess 46. In the case of suction holding such a reference jig 40* with the mounting tool 15, the suction force acts only on the part of the reference jig 40* that opposes the suction hole 28. Since the suction hole 28 is very small compared to the reference jig 40*, in this case, excessive stress concentration may occur in the part of the reference jig 40* opposing the suction hole 28, potentially causing damage to the reference jig 40 *. Moreover, in the case where the area on which the suction force acts is small, it may become difficult to maintain the gravity balance when suction holding the reference jig 40*, potentially causing the reference jig 40 to tilt or fall.

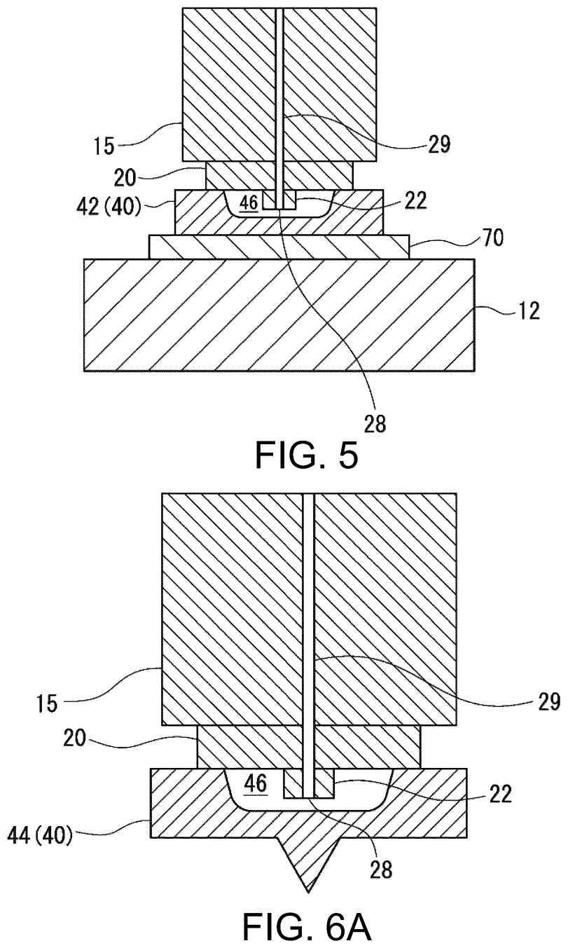

Therefore, in this example, a receiving recess 46 for receiving the second block 22 is formed on the upper surface of the reference jig 40. By adopting this configuration, as shown in FIG. 5, in the case of suction holding the reference jig 40, the suction force acts on the entire receiving recess 46. Since the receiving recess 46 is sufficiently larger than the suction hole 28, compared to the comparative example in FIG. 8, stress concentration may be mitigated, and the gravity balance may be more easily maintained.

In addition, in this example, the receiving recess 46 is formed in a shape without sharp corners. Specifically, as shown in FIG. 2 and FIG. 3, the receiving recess 46 is formed in a shape with corners that have undergone fillet treatment. This configuration is adopted to prevent stress concentration at the corners when suction holding the reference jig 40. Moreover, the larger the external size of the receiving recess 46, the more the stress concentration is mitigated and the more stable the gravity balance becomes. Therefore, the external size of the receiving recess 46 may be 50% or more, or 80% or more of the external size of the reference jig 40.

In any case, as evident from the above description, according to the manufacturing apparatus 10 of this example, both the semiconductor chip 60 and the reference jig 40 can be appropriately transferred using a single mounting tool 15. Moreover, the description so far is an example. Therefore, as long as the mounting tool 15 includes a base surface 26 that contacts the upper surface of the reference jig 40 and a suction protrusion protruding from the base surface 26, and the reference jig 40 includes a receiving recess 46 that receives the suction protrusion, other configurations may be modified.

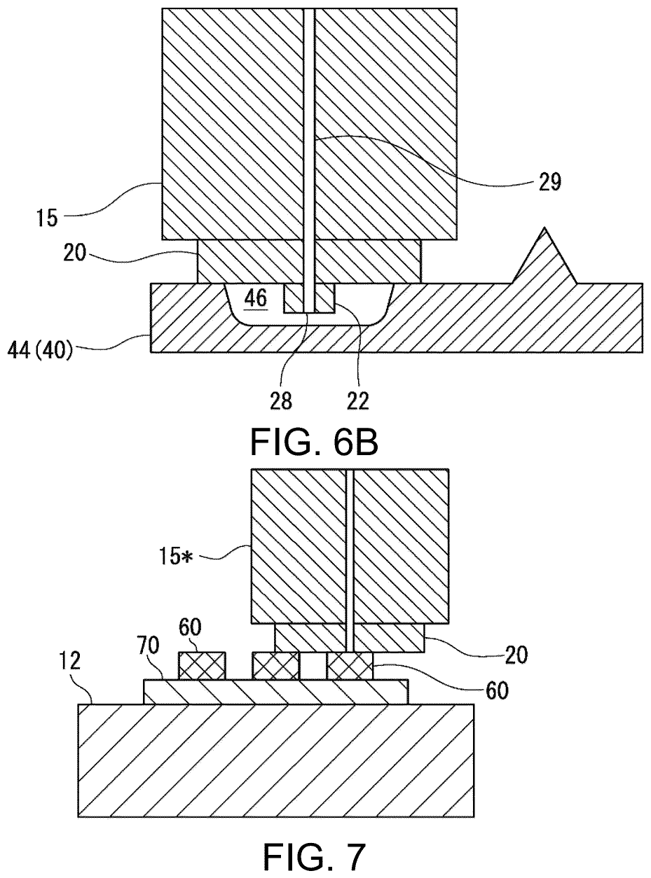

For example, in the above example, the calibration jig 42 was cited as an example of the reference jig 40, but the reference jig 40 may be another jig as long as it is larger than the semiconductor chip 60 and may be suction held by the mounting tool 15. For instance, the reference jig 40 may be a measurement jig 44 as shown in FIG. 6A. This measurement jig 44 is used in measuring the parallelism of the stage 12 or the substrate 70. The measurement jig 44 shown in FIG. 6A includes a flat plate and a cone protruding downward from the flat plate. When measuring the parallelism of the measurement target surface, while the measurement jig 44 is suction held by the mounting tool 15, the tip of the cone is sequentially brought into contact with two or more points on the measurement target surface. Then, the parallelism is measured based on the height of the mounting tool 15 at each point of contact. A receiving recess 46 for receiving the second block 22 may also be formed on the upper surface of such a measurement jig 44.

Furthermore, the reference jig 40 may be a measurement jig 44 as shown in FIG. 6B. The measurement jig 44 shown in FIG. 6B includes a flat plate and a cone protruding upward from the flat plate. In this case, while the measurement jig 44 is suction held by the mounting tool 15, the measurement jig 44 is placed on the stage 12 or the substrate 70. Moreover, subsequently, the tip of the cone is brought into contact with two or more points on the bottom surface of the mounting tool 15, and the parallelism is measured based on the height of the mounting tool 15 at each point of contact. A receiving recess 46 for receiving the second block 22 may also be formed on the upper surface of such a measurement jig 44. In this case, of course, the receiving recess 46 is formed in a position that avoids the cone.

Furthermore, as long as the receiving recess 46 may completely receive the second block 22, its shape and size may be appropriately modified. For example, the receiving recess 46 may have a shape with sharp corners. Also, the external size of the receiving recess 46 may be less than 50% of the external size of the reference jig 40. Furthermore, the first block 20 and the second block 22 may be integrated with the mounting tool 15 or may be detachable from the mounting tool 15. For instance, the first block 20 and the second block 22 may be attachments that are detachable from the mounting tool 15.

### REFERENCE SIGNS LIST

10 Manufacturing apparatus
12 Stage
14 Mounting head
15 Mounting tool
20 First block
22 Second block
24 Suction surface
26 Base surface
28 Suction hole
29 Suction channel
30 Suction pump
40 Reference jig
42 Calibration jig
44 Measurement jig
46 Receiving recess
60 Semiconductor chip
70 Substrate

1. A semiconductor device manufacturing apparatus, comprising:
a reference jig larger in size than a semiconductor chip; and
a mounting tool that individually suctions and transfers the semiconductor chip and the reference jig,
wherein the mounting tool comprises:
a base surface that contacts an upper surface of the reference jig when the reference jig is suction held; and
a suction protrusion that protrudes from the base surface and has a suction hole formed therein, the suction protrusion contacting an upper surface of the semiconductor chip when the semiconductor chip is suction held, and
wherein the reference jig has a receiving recess, in which the receiving recess receives the suction protrusion and forms a closed space between itself and the mounting tool when suction held by the mounting tool.

2. The semiconductor device manufacturing apparatus according to claim 1,
wherein an external size of the suction protrusion is smaller than an external size of the semiconductor chip.

3. The semiconductor device manufacturing apparatus according to claim 1,
wherein the receiving recess does not have sharpened corners.

4. The semiconductor device manufacturing apparatus according to claim 1,
wherein the reference jig is a calibration jig or a measurement jig.

5. The semiconductor device manufacturing apparatus according to claim 1,
wherein an external size of the receiving recess is 50% or more of an external size of the reference jig.

6. A method for suctioning member that individually suctions a semiconductor chip and a reference jig larger in size than the semiconductor chip by one mounting tool,
wherein the mounting tool comprises a base surface and a suction protrusion protruding from the base surface and having a suction hole formed therein,
the reference jig has, on its upper surface, a receiving recess formed that completely accommodates the suction protrusion formed,
the suction protrusion is brought into contact with the semiconductor chip when the semiconductor chip is suctioned by the mounting tool, and
the base surface is brought into contact with the upper surface of the reference jig in a state where the suction protrusion is accommodated in the receiving recess when the reference jig is suctioned by the mounting tool.
